(19) United States
(12) Patent Application Publication
(10) Pub. No.: US 2006/0220019 A1
(43) Pub. Date: Oct. 5, 2006

(54) Liquid crystal display

(76) Inventors: Ji-Won Sohn, Seoul (KR); Nak-Cho Choi, Seoul (KR); Jae-Jin Lyu, Gwangju-si (KR)

Correspondence Address: CANTOR COLBURN, LLP, 55 GRIFFIN ROAD SOUTH, BLOOMFIELD, CT, 06002, US

(21) Appl. No.: 11/393,331

(22) Filed: Mar. 30, 2006

(30) Foreign Application Priority Data
Mar. 30, 2005 (KR) 10-2005-0026541

(51) Int. Cl. H01L 29/04

(52) U.S. Cl. 257/59

(57) ABSTRACT

A liquid crystal display including: a panel; a first electric field generating electrode formed on the panel; a second electric field generating electrode opposed to the first electric field generating electrode; a liquid crystal layer disposed between the first electric field generating electrode and the second electric field generating electrode; a slope member formed on the panel and including a ridge and a slope; and a plurality of hollows formed in a cut portion of the second electric field generating electrode.

This application claims priority to Korean Patent Application No. 2005-0026541, filed on Mar. 30, 2005, and all the benefits accruing therefrom under 35 U.S.C. §119, and the contents of which in its entirety are herein incorporated by reference.

### BACKGROUND OF THE INVENTION

(a) Field of the Invention

The present invention relates to a display panel and a liquid crystal display having the display panel.

(b) Description of the Related Art

A liquid crystal display, which is one of the most widely used flat panel displays, includes two panels having electric field generating electrodes such as pixel electrodes and a common electrode, and a liquid crystal layer interposed therebetween. The liquid crystal display displays images by applying a voltage to the electric field generating electrodes, generating an electric field in the liquid crystal layer, and determining alignment of liquid crystal molecules in the liquid crystal layer to control polarization of incident light.

Among such liquid crystal displays, a liquid crystal display with a vertical alignment mode in which liquid crystal molecules are arranged such that major axes of the liquid crystal molecules are perpendicular to the upper and lower panels in the state that no electric field is generated has attracted attention, since it has a high contrast ratio and can easily provide a wide reference viewing angle.

As methods of embodying a wide viewing angle in a liquid crystal display with a vertical alignment mode, there are known a method of forming cut portions in the electric field generating electrodes, a method of forming protrusions on the electric field generating electrodes, and the like. Since the direction in which the liquid crystal molecules are tilted can be determined by the use of the cut portions and the protrusions, the reference viewing angle can be widened by variously arranging the cut portions and the protrusions to distribute the tilt direction of the liquid crystal molecules in various directions.

However, in the method of forming the cut portions, a particular mask is required for patterning the common electrode, and an overcoat layer should be formed on a color filter so as to prevent pigments of the color filter from leaking and contaminating the liquid crystal layer through the cut portions of the common electrode.

In addition, the liquid crystal display with a vertical alignment mode having the protrusions or the cut portions has a slow response speed. This is partially because the cut portions or the protrusions strongly regulate the liquid crystal molecules close thereto but weakly regulate the liquid crystal molecules apart therefrom.

### SUMMARY OF THE INVENTION

An embodiment of the present invention provides a liquid crystal display that can rapidly change alignment of liquid crystal molecules by minimizing the liquid crystal molecules not affected by a fringe field, and that has an enhanced domain regulation power.

One exemplary embodiment according to the present invention provides a liquid crystal display including: a panel; a first electric field generating electrode formed on the panel; a second electric field generating electrode opposed to the first electric field generating electrode; a liquid crystal layer disposed between the first electric field generating electrode and the second electric field generating electrode; a slope member formed on the panel and comprising a ridge and a slope; and a plurality of hollows formed in a cut portion of the second electric field generating electrode.

Another exemplary embodiment according to the present invention provides A method of forming a liquid crystal display including: forming a first electric field generating electrode panel; forming a second electric field generating electrode opposite the first electric field generating electrode; disposing a liquid crystal layer between the first electric field generating electrode and the second electric field generating electrode; forming a slope member on the panel, the slope member comprising a ridge and a slope; and forming a plurality of hollows in a cut portion of the second electric field generating electrode.

### BRIEF DESCRIPTION OF THE DRAWINGS

The above and other features and advantages of the present invention will become more apparent by describing in detail exemplary embodiments thereof with reference to the attached drawings in which:

FIG. 1 is a layout diagram illustrating an exemplary embodiment of a liquid crystal display according to the present invention;

FIG. 2 is a layout diagram illustrating an exemplary embodiment of a thin film transistor panel of the liquid crystal display illustrated in FIG. 1;

FIG. 3 is a layout diagram illustrating an exemplary embodiment of a common electrode panel of the liquid crystal display illustrated in FIG. 1;

FIG. 4 is a cross-sectional view of the liquid crystal display taken along line IV-IV′-IV″-IV′″ of FIG. 1;

FIG. 5 is a diagram illustrating an exemplary embodiment of liquid crystal molecules aligned to be parallel to a depth direction of a plurality of hollows formed in cut portions according to the present invention;

FIG. 6 is a perspective view illustrating an exemplary embodiment of a concave portion and a convex portion formed in a slope member according to the present invention;

FIG. 7 is a diagram illustrating an exemplary embodiment of a plane pattern of the concave portion and the convex portion illustrated in FIG. 6;

FIG. 8 is a layout diagram illustrating another exemplary embodiment of a liquid crystal display according to the present invention;

FIG. 9 is a layout diagram illustrating another exemplary embodiment of a liquid crystal display according to the present invention;

FIG. 10 is a cross-sectional view of the liquid crystal display taken along line X-X′-X″-X′″ of FIG. 9;

FIG. 11 is a cross-sectional view taken along line IV-IV′-IV″-IV′″ of FIG. 1 as an exemplary embodiment of the cross-sectional view of the liquid crystal display illustrated in FIGS. 1 to 3;

FIG. 12 is a cross-sectional view taken along line IV-IV′-IV″-IV′″ of FIG. 1 as another exemplary embodiment of the cross-sectional view of the liquid crystal display illustrated in FIGS. 1 to 3; and

FIG. 13 is a cross-sectional view of an exemplary embodiment of a slope member according to the present invention.

### DETAILED DESCRIPTION OF THE INVENTION

Hereinafter, exemplary embodiments of the present invention will be described in detail with reference to the attached drawings such that the present invention can be easily put into practice by those skilled in the art. However, the present invention is not limited to the exemplary embodiments, but may be embodied in various forms.

In the drawings, thicknesses are enlarged so as to clearly illustrate layers and areas. In addition, like elements are denoted by like reference numerals in the whole specification. If it is mentioned that a layer, a film, an area, or a plate is placed on a different element, it includes a case that another element is disposed therebetween, as well as a case that the layer, film, area, or plate is placed right on the different element. On the contrary, if it is mentioned that one element is placed right on another element, it means that no element is disposed therebetween.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “below”, “lower”, “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Liquid crystal displays according to the exemplary embodiments of the present invention will be now described in detail with reference to the accompanying drawings.

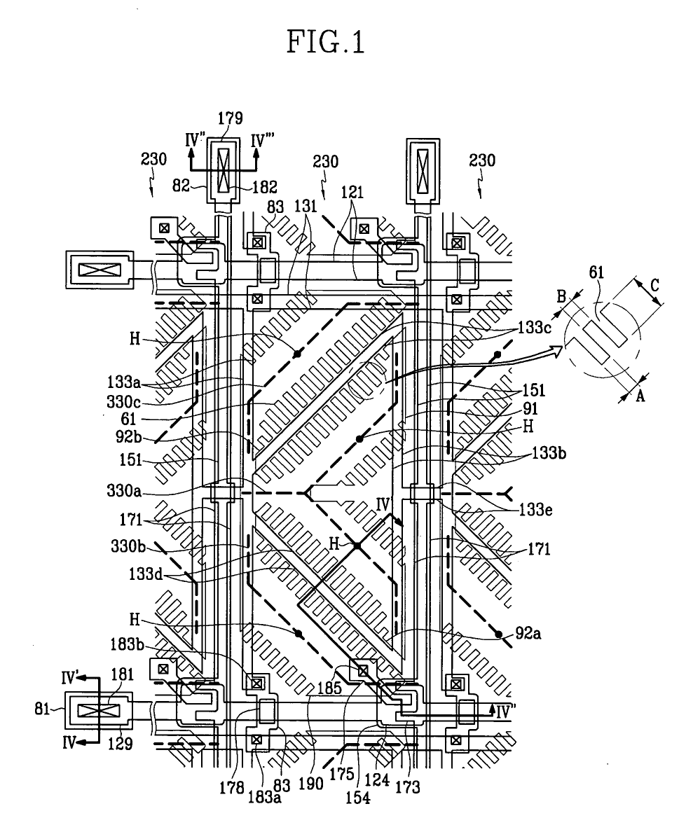

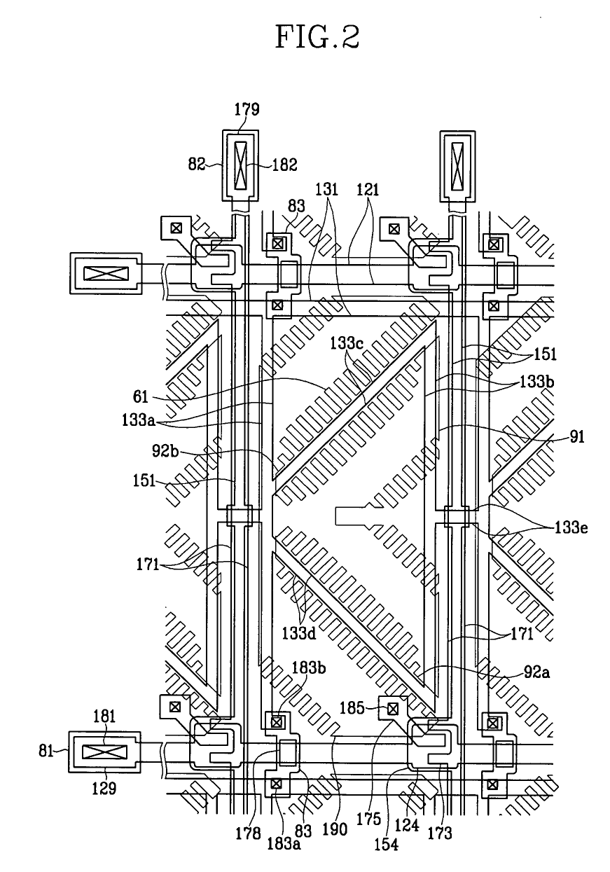

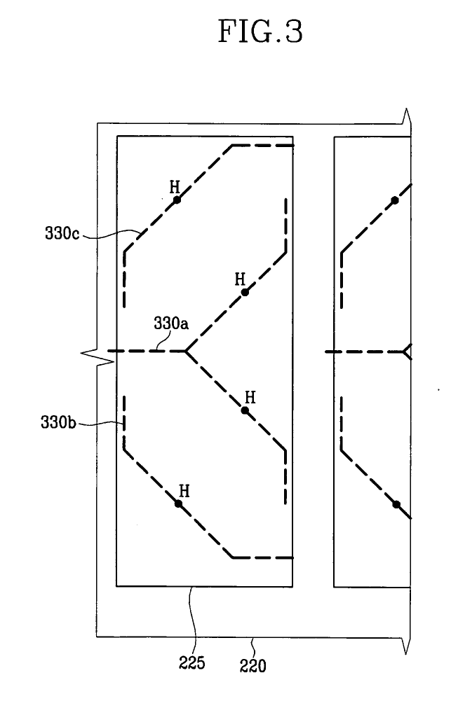

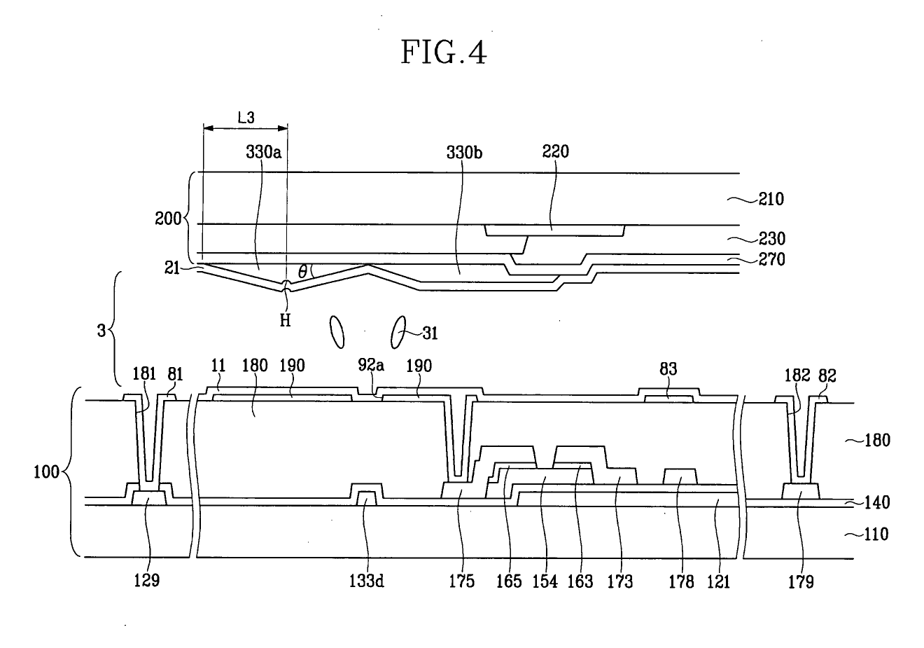

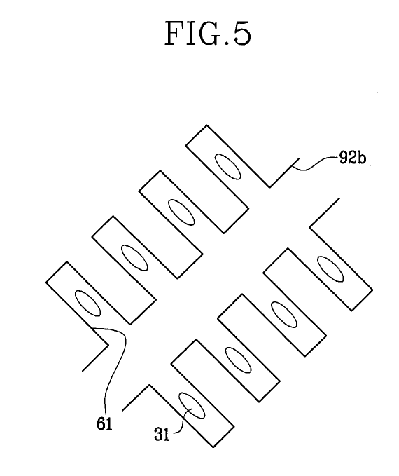

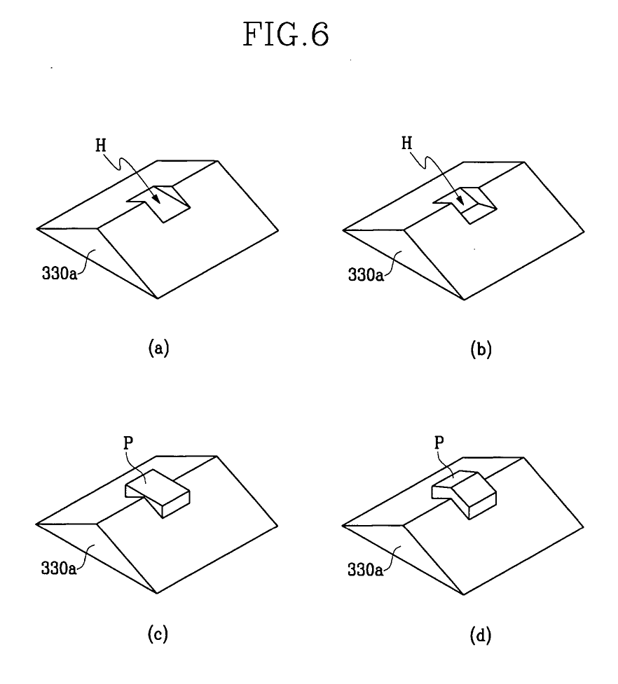

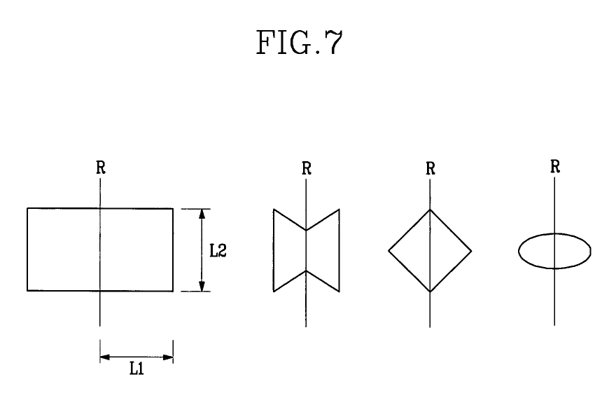

FIG. 1 is a layout diagram illustrating an exemplary embodiment of a liquid crystal display according to the present invention, FIG. 2 is a layout diagram illustrating an exemplary embodiment of a thin film transistor panel of the liquid crystal display illustrated in FIG. 1, FIG. 3 is an exemplary embodiment of a layout diagram illustrating a common electrode panel of the liquid crystal display illustrated in FIG. 1, FIG. 4 is a cross-sectional view of the liquid crystal display taken along line IV-IV′-IV″-IV′″ of FIG. 1, FIG. 5 is a diagram illustrating an exemplary embodiment of liquid crystal molecules aligned to be parallel to a depth direction of a plurality of hollows formed in cut portions according to the present invention, FIG. 6 is a perspective view illustrating an exemplary embodiment of a concave portion and a convex portion formed in a slope member according to the present invention, and FIG. 7 is a diagram illustrating an exemplary embodiment of a plane pattern of the concave portion and the convex portion illustrated in FIG. 6

An exemplary embodiment of the liquid crystal display according to the present invention includes a thin film transistor panel 100 and a common electrode panel 200 opposed to each other, and a liquid crystal layer 3 interposed between the panels 100 and 200.

First, the thin film transistor panel 100 is described in detail with reference FIGS. 1, 2, and 4.

A plurality of gate lines 121 and a plurality of storage electrode lines 131 are formed on an insulating panel 110.

The gate lines 121 serve to supply gate signals, and extend substantially horizontally to be separated from each other. Each gate line 121 has a plurality of gate electrodes 124 protruded upwardly and downwardly, and a large-area end portion 129 for connection to other layers or driver circuits. In exemplary embodiments, when driver circuits (not shown) are integrated on the thin film transistor panel 100, the gate lines 121 may extend for connection to the driver circuit.

Each storage electrode line 131 extends substantially horizontally and is disposed between two pairs of neighboring or adjacent gate lines 121 so as to be closer to the upper pair of gate lines 121. Each storage electrode line 131 includes plural sets of branches 133a to 133d and a plurality of connections 133e.

Each set of branches includes first and second storage electrodes 133a and 133b extending substantially vertically to be separated from each other, and third and fourth storage electrodes 133c and 133d extending substantially obliquely to connect the first storage electrode 133a and the second storage electrode 133b to each other.

The first storage electrode 133a has a fixed end connected to the corresponding storage electrode line 131 and a free end having a protruded portion positioned opposite to the fixed end or portion.

The third and fourth storage electrodes 133c and 133d are connected to both ends of the second storage electrode 133b in the vicinity of or proximate to the center of the first storage electrode 133a. The third and fourth storage electrodes 133c and 133d form inversion symmetry about a center line between the two neighboring pairs of gate lines 121. The connections 133e connect the first storage electrode 133a and the second storage electrode 133b adjacent to each other in neighboring sets of or adjacent storage electrodes 133a to 133d.

The storage electrode lines 131 are supplied with a predetermined voltage such as a common voltage which is supplied to a common electrode 270 of the common electrode panel 200. In exemplary embodiments each storage electrode line 131 may have a pair of stem lines (not shown) extending substantially horizontally.

In exemplary embodiments the gate lines 121 and the storage electrode lines 131 may be made of a silver-grouped metal, including, but not limited to, silver (Ag) or a silver alloy, an aluminum-grouped metal including, but not limited to, aluminum (Al) or an aluminum alloy, a copper-grouped metal including, but not limited to, copper (Cu) or a copper alloy, a molybdenum-grouped metal including, but not limited to, molybdenum (Mo) or a molybdenum alloy, chromium, titanium, or tantalum. In alternative exemplary embodiments, the gate lines 121 and the storage electrode lines 131 may have a multi-layered structure including two conductive layers (not shown) having different physical properties. One conductive layer thereof may be made of a metal having low resistivity such as an aluminum-grouped metal, a silver-grouped metal, a copper-grouped metal or a combination including at least one of the foregoing, so as to reduce delay of signals or voltage drop. The other conductive layer may be made of a metal having excellent physical, chemical, and electrical contact characteristics with ITO (Indium Tin Oxide) or IZO (Indium Zinc Oxide), such as a molybdenum-grouped metal, chromium (Cr), titanium (Ti), tantalum (Ta) or a combination including at least one of the foregoing. In one exemplary embodiment, such a combination may include a combination of a chromium lower layer and an aluminum (alloy) upper layer and a combination of an aluminum (alloy) lower layer and a molybdenum (alloy) upper layer. In other alternative exemplary embodiments, the gate lines 121 and the storage electrode lines 131 may be made of various metals and conductive materials such as is suitable for the purposes described herein.

Referring to FIG. 4, Side surfaces of the gate lines 121 and the storage electrode lines 131 are sloped with respect to a surface of the insulating panel 110. In exemplary embodiments, the slope angle may be in the range of about 30° to about 80°.

Agate insulating layer 140 including, but not limited to, silicon nitride (SiNₓ) or the like, is formed on the gate lines 121 and the storage electrode lines 131.

Referring again to FIGS. 1 and 2, a plurality of line-shaped semiconductor patterns 151 that may include, but are not limited to, hydrogenated amorphous silicon (where amorphous silicon can be abbreviated as a-Si) or polysilicon are formed on the gate insulating layer 140. Each line-shaped semiconductor pattern 151 extends substantially vertically and includes a plurality of extensions 154 extending toward the gate electrodes 124.

The line-shaped semiconductor patterns 151 are widened in the vicinity of the gate lines 121 and the storage electrode lines 131 so as to widely cover or encompass them.

Referring again to FIG. 4, a plurality of line-shaped and island-shaped ohmic contact members 161 and 165 are formed on the semiconductor patterns 151. The ohmic contact members 161 and 165 may be made of silicide or a material such as n+ hydrogenated amorphous silicon which is doped with n-type impurities such as phosphorous in a high concentration Each line-shaped ohmic contact member 161 has a plurality of extensions 163, and the extensions 163 and the island-shaped ohmic contact members 165, which form pairs, are formed on the extensions 154 of the semiconductor patterns 151.

Side surfaces of the semiconductor patterns 151 and the ohmic contact members 161 and 165 are also sloped with respect to the surface of the insulating panel 110. In exemplary embodiments, the slope angle may be in the range of about 30° to about 80°.

A plurality of data lines 171, a plurality of drain electrodes 175, and a plurality of isolated metal pieces 178 are formed on the ohmic contact members 161 and 165 and the gate insulating layer 140.

The data lines 171 serve to deliver the data voltages, and extend substantially in a vertical direction to intersect (or be perpendicular to) the gate lines 121 at substantially a right angle. The data lines 171 also intersect the storage electrode lines 131 and the connections 133e. The data lines 171 are disposed between the first storage electrode 133a and the second storage electrode 133b adjacent to each other in the neighboring branch sets of the storage electrode lines 131. Each data line 171 includes a plurality of source electrodes 173 extending toward the gate electrodes 124, and a large-area end portion 179 for connection to another layer or an external device (not shown). When a data driving circuit (not shown) for generating data voltages is integrated on the insulating panel 110, the data lines 171 may extend so as to be connected directly to the data driving circuit.

Each drain electrode 175 includes a large-area end portion for connection to another layer and bar-shaped end portions positioned on the gate electrodes 124. The source electrodes 173 are curved to surround a part of the bar-shaped end portions.

One gate electrode 124, one source electrode 173, and one drain electrode 175 constitute one thin film transistor (TFT) together with the extension 154 of the semiconductor pattern 151. A channel of the thin film transistor is formed in the extension 154 between the source electrode 173 and the drain electrode 175.

The metal pieces 178 are disposed on the gate lines 121 in the vicinity of the end portions of the storage electrodes 133a.

In exemplary embodiments, the data lines 171, the drain electrodes 175, and the metal pieces 178 may include, but are not limited to, a refractory metal such as a molybdenum-grouped metal, chromium, tantalum, titanium, or alloys thereof, and may have a multi-layered structure including a conductive layer (not shown) made of a refractory metal or the like and a conductive layer (not shown) having low resistance. One exemplary embodiment of the multi-layered structure may include a double-layered film including a chromium or molybdenum (alloy) lower layer and an aluminum (alloy) upper layer and a triple-layered film including a molybdenum (alloy) lower layer, an aluminum (alloy) intermediate layer, and a molybdenum (alloy) upper layer. In alternative exemplary embodiments, the data lines 171, the drain electrodes 175, and the metal pieces 178 may be made of a variety of metal and conductive materials such as is suitable for the purposes described herein.

Similar to the gate lines 121 and the storage electrode lines 131, the side surfaces of the data lines 171 and the drain electrodes 175 may be sloped with respect to the surface of the insulating panel 110. In exemplary embodiments, the slope angle may be in the range of about 30° to about 80°.

The ohmic contact members 161 and 165 exist only between the semiconductor patterns 151 at a lower side (or end) and the data lines 171 and the drain electrodes 175 at an upper side The ohmic contact members 161 and 165 serve to decrease the ohmic resistance. The line-shaped semiconductor patterns 151 have portions that are exposed between the source electrodes 173 and the drain electrodes 175 and that are not covered with the data lines 171 and the drain electrodes 175. A width of the line-shaped semiconductor patterns 151 is relatively smaller than the width of the data lines 171 at most places. As described above, the width of the line-shaped semiconductor patterns 151 becomes relatively greater at places where the gate lines 121 and the storage electrode lines 131 intersect each other so as to smooth the profile of the surface, thereby preventing a short circuit of the data lines 171.

A passivation layer 180 is formed on the data lines 171, the drain electrodes 175, and the metal pieces 178, and on the exposed portions of the semiconductor patterns 151 not covered by the data lines 171, the drain electrodes 175, and the metal pieces 178. In exemplary embodiments, the passivation layer 180 may be made of an inorganic insulating material such as silicon nitride and silicon oxide, an organic insulating material, or insulating material having a low dielectric constant or a combination including at least one of the foregoing. In other exemplary embodiments, the dielectric constant of the insulating material is 4.0 or less. One other exemplary embodiment thereof may include a-Si:C:O and a-Si:O:F formed by the use of a plasma enhanced chemical vapor deposition (PECVD) method.

In other exemplary embodiments, the passivation layer 180 may be made of an organic insulating material having photosensitivity, and the surface thereof may be flat. In alternative exemplary embodiments, the passivation layer 180 may have a double-layered structure including an inorganic lower layer and an organic upper layer so as to secure the excellent insulating characteristic of the organic layer and to not damage the exposed portions of the semiconductor patterns 151.

A plurality of contact holes 182 and 185 for exposing the end portions of the data lines 171 and the large-area end portions of the drain electrodes 175 are formed in the passivation layer 180. A plurality of contact holes 181 for exposing the end portions 129 of the gate lines 121, a plurality of contact holes 183a for exposing a part of the storage electrode lines 131 in the vicinity of the fixed ends of the first storage electrodes 133a, and a plurality of contact holes 183b for exposing the extensions of the free ends of the first storage electrodes 133a are formed in the passivation layer 180 and the gate insulating layer 140.

A plurality of pixel electrodes 190, a plurality of contact assistants 81 and 82, and a plurality of overpasses 83 are formed on the passivation layer 180. The pixel electrodes 190, contact assistants 81 and 82, and overpasses 83 may be made of, but are not limited to, a transparent conductive material such as ITO and IZO, a metal having excellent reflectivity such as aluminum and a silver alloy and a combination including at least one of the foregoing. The pixel electrodes 190 are physically and electrically connected to the drain electrodes 175 through the contact holes 185, and are supplied with the data voltages from the drain electrodes 175. The pixel electrodes 190 supplied with the data voltage generate an electric field together with the common electrode 270, thereby determining the alignment of liquid crystal molecules 31 of the liquid crystal layer 3.

The pixel electrodes 190 and the common electrode 270 constitute capacitors (hereinafter, referred to as “liquid crystal capacitors”), and they hold supplied voltage after the thin film transistors are turned off. In exemplary embodiments in order to reinforce the voltage holding ability, other capacitors (not shown) which are referred to as storage capacitors may be disposed in parallel to the liquid crystal capacitors. In other exemplary embodiments, the storage capacitors may be formed by overlapping the pixel electrodes 190 with the storage electrode lines 131. The common electrode may cover or be formed on a substantially whole surface of the common electrode panel 200.

In exemplary embodiments, the pixel electrode 190 may be chamfered at the left corner thereof. The chamfered oblique side may form an angle of about 45° with respect to the gate lines 121.

A central cut portion 91, a lower cut portion 92a, and an upper cut portion 92b are formed in each pixel electrode 190. Each pixel electrode 190 is divided into a plurality of partitions by the cut portions 91, 92a, and 92b. The cut portions 91, 92a, and 92b form inversion symmetry about a virtual horizontal center line dividing the pixel electrode 190 into two halves, including an upper half and a lower half of the pixel electrode.

The lower and upper cut portions 92a and 92b extend obliquely from a right edge of the pixel electrode 190 to the left edge thereof, and overlap with the third and fourth storage electrodes 133c and 133d. The lower and upper cut portions 92a and 92b are disposed in the lower half and the upper half with respect to the horizontal center line of the pixel electrode 190, respectively. The lower and upper cut portions 92a and 92b extend substantially perpendicular to each other to form an angle of about 45° with respect to the gate lines 121.

The central cut portion 91 extends along the virtual horizontal center line of the pixel electrode 190, and has an entrance its right edge. The entrance of the central cut portion 91 has a pair of oblique sides that are substantially parallel to the lower cut portion 92a and the upper cut portion 92b, respectively.

Essentially, the lower half of the pixel electrode 190 is divided into two partitions by the lower cut portion 92a, and the upper half of the pixel electrode 190 is also divided into two partitions by the upper cut portion 92b. In alternative embodiments, the number of partitions or the number of cut portions can vary depending upon design factors such as the size of the pixel, the aspect ratio of the pixel electrode, and the kind or characteristics of the liquid crystal layer 3.

Referring to FIG. 1, a plurality of hollows 61 are formed in the cut portions 91, 92a, and 92b of the pixel electrode 190. The hollows may also be formed on the oblique side of the pixel electrode 190. The hollows 61 are formed to be substantially perpendicular to the length or longitudinal direction of the cut portions 91, 92a, and 92b. The alignment of the liquid crystal molecules 31 in desired directions may be controlled by the hollows 61.

In exemplary embodiments, in order to prevent loss of aperture ratio due to the hollows 61, a width “A” of the hollows 61 may be in the range of 1 μm to about 4 μm and that a gap “B” between the hollows 61 is in the range of about 1 μm to about 4 μm. The width “A” of the hollows 61 may be constant at the entrance of the hollows 61 and the bottom of the hollows 61. In alternative embodiments, the width “A” may vary from the entrance to the bottom of the hollows 61.

In other exemplary embodiments, a depth “C” of the hollows 61 becomes smaller or decreases in a direction toward both ends of the cut portions 91, 92a, and 92b from the center of the cut portions 91, 92a, and 92b. The contact assistants 81 and 82 are connected to the end portions 129 of the gate lines 121 and the end portions 179 of the data lines 171 through the contact holes 181 and 182, respectively. The contact assistants 81 and 82 essentially serve to reinforce adhesion between the end portions 129 and 179 of the gate lines 121 and the data lines 171, respectively, and an external device, and to protect them.

The overpasses 83 cross the gate lines 121 and are connected to the exposed end portions of the free ends of the first storage electrodes 133a and the exposed portions of the storage electrode lines 131 through the contact holes 183a and 183b positioned on both sides of the gate lines 121. In exemplary embodiments, the overpasses 83 may overlap with the metal pieces 178, and may be electrically connected to the metal pieces 178. In other exemplary embodiments, the storage electrode lines 131 including the storage electrodes 133a to 133d may be used together with the overpasses 83 and the metal pieces 178 to essentially repair defects of the gate lines 121, the data lines 171, or the thin film transistors. In one exemplary embodiment, when repairing the gate lines 121, the gate lines 121 and the storage electrode lines 131 are electrically connected to each other by irradiating a laser beam to intersections between the gate lines 121 and the overpasses 83 to connect the gate lines 121 to the overpasses 83. The metal pieces 178 serve to reinforce the electrical connection between the gate lines 121 and the overpasses 83.

Next, an exemplary embodiment of the common electrode panel 200 will be described with reference to FIGS. 1, 3, and 4.

A light blocking member 220 is formed on an insulating panel 210. The light blocking member 220 may include, but is not limited to, a black matrix. The insulating panel 210 may be made of transparent glass or the like. The light blocking member 220 has a plurality of openings 225 which are disposed substantially opposite the pixel electrodes 190. The openings 225 may have a shape that substantially corresponds to the pixel electrodes 190. In exemplary embodiments, the light blocking member 220 may include only linear portions extending along the data lines 171. In other exemplary embodiments, the light blocking member 220 may further include portions opposed to the thin film transistors. In other exemplary embodiments, the light blocking member 220 may be formed out of a single-layered film of chromium, a double-layered film of chromium and chromium oxide, or an organic layer including a black pigment.

A plurality of color filters 230 is formed on the insulating panel 210. The color filters 230 may be disposed in the openings 225 of the light blocking member 220. The color filters 230 may extend in a substantially vertical direction along the pixel electrodes 190. Each color filter 230 may display one of a group of colors. In exemplary embodiments, the colors may include, but are not limited to, three colors of red, green, and blue. In other exemplary embodiments, edges of neighboring color filters 230 may overlap with each other.

In exemplary embodiments, the common electrode 270 may be made of a transparent conductive material such as ITO or IZO. The common electrode 270 may be formed on the color filters 230.

An overcoat layer (not shown) for preventing the color filters 230 from being exposed and providing a substantially flat plane may be formed between the common electrode 270 and the color filters 230.

A plurality of sets of slope members 330a, 330b, and 330c are formed on the common electrode 270. In exemplary embodiments, it is preferable that the slope members 330a to 330c include a dielectric material, and that the dielectric constant thereof is less than or equal to the dielectric constant of the liquid crystal layer 3.

In one exemplary embodiment, each set of slope members includes the three slope members 330a to 330c opposed to a corresponding pixel electrode 190. Each slope member 330a to 330c may have a substantially trapezoidal shape or a chevron shape including a primary edge and a secondary edge. The primary edge may be substantially parallel to the oblique sides of the cut portions 91, 92a, and 92b and the oblique side of the corresponding pixel electrode 190, and is opposed to the oblique sides of the cut portions 91, 92a, and 92b or the oblique side of the corresponding pixel electrode 190. The secondary edge is substantially parallel to the corresponding gate line 121 and the corresponding data line 171.

Each slope member 330a to 330c may include a ridge and a slope, indicated by thick dot lines in the figures. The ridge is disposed between the cut portions 91, 92a, and 92b of the pixel electrode 190 or between the cut portions 92a and 92b and the oblique side of the corresponding pixel electrode 190, and extends substantially parallel to a longitudinal direction of the cut portions 91, 92a, and 92b. The bottom of the slope of the slope member is opposed to cut portions 91, 92a, and 92b.

The slope is a plane from the ridge to the primary edge, and it gradually decreases in height. A plane defined by edges opposite the ridge of two slopes may be considered the bottom of the slope member. Two slopes extending from the ridge and the bottom of the slope member may form a substantially triangular shaped plane side of the slope member as illustrated in FIG. 6. A height of the ridge may be considered a distance or length taken from the peak of the triangle (the ridge) and perpendicular to the base of the triangle (or the bottom of the slope member). A height of the slope may be considered a distance taken from an edge of or a point along the slope forming the oblique sides of the triangle and perpendicular to the base of the triangle (or the bottom of the slope member). It is preferable that the height of the ridge is in the range of about 0.5 to 2.0 μm and that the slope angle θ of the slope is in the range of about 1 to 10°.

In exemplary embodiments, an area occupied by a set of slope members 330a to 330c is greater than or equal to a half of the area of the corresponding pixel electrode 190. The area occupied by the set of slope members 330a to 330c may be considered a maximum area delimited by edges of the slope member when viewed from the top of the slope member. In other exemplary embodiments, the slope members 330a to 330c in the neighboring pixel electrodes 190 may be connected to each other.

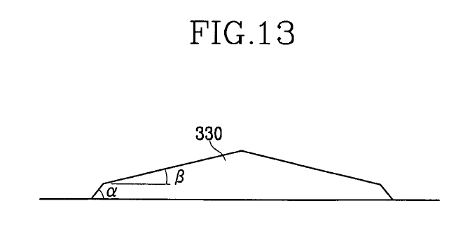

In exemplary embodiments, the slopes of the slope members 330a to 330c may be substantially flat or planar as illustrated in FIG. 6. In alternative embodiments, the slope of the slope members 330a to 330c may be bent in an intermediate position thereof, as shown in FIG. 13. In one exemplary embodiment the slope angle of the slope at a portion closer to the bottom (or at a point further away from the ridge) is less than or equal to α=10°. The slope angle at the portion closer to the ridge is less than or equal to β=5°. FIG. 13 is a cross-sectional view of an exemplary embodiment of a slope member according to the present invention.

Referring to FIG. 6, a concave portion H is formed substantially at the center of the ridge of each slope member 330a to 330c. The concave portion H may be replaced with various shapes of concave portions H or convex portions P, as shown in the exemplary embodiments (a) to (d) of FIG. 6. Two or more concave portions H or two or more convex portions P (hereinafter, referred to as “singular portions”) may be formed in each ridge.

As shown in FIG. 6, the bottom surface of the concave portion H may be (a) flat or (b) curved, and the top surface of the convex portion P may be (c) flat or (d) curved. “Curved” with respect to (b) or (d) may be taken to mean that two or more faces of the singular portions are disposed at an angle relative to each other. For example, the curved surface of (d) includes two faces of the top surface of the convex portion P as being “bent” or angled relative to each other.

As shown in FIG. 7, the shape of the singular portions H and P in a top view may be substantially a rectilinear shape, a circular shape, an elliptical shape, or a polygonal shape, which is substantially symmetric about the ridge R. In alternative embodiments, the singular portions H and P may be disposed to be non-symmetrical about the ridge and/or non-centered along the ridge.

A width L1 of the singular portions H and P may be considered as a length from the ridge to an edge of the singular portion in a direction extending from the ridge R toward the primary edge of the slope member as the slope member is viewed from the top. A length L2 may be considered as a distance between two edges of the singular portion taken in a direction substantially parallel to the ridge R. In one exemplary embodiment, it is preferable that the width L1 of the singular portions H and P from the ridge is in the range of about 10 μm to about 15 μm and that the length L2 of the singular portions H and P along the ridge is about 10 μm or less. The shape and size of the singular portion H and P are not limited to the above-mentioned shape and size, but may be variously changed in alternative embodiments such as is suitable for the purposes described herein.

In exemplary embodiments, a concave portion H or a convex portion P can be formed by applying an organic material and then performing a photolithography process or a photolithographic etching process using a mask. By forming slits or translucent films for controlling the amount of exposing light in the mask, different amounts of exposing light are used for the concave portion or the convex portion and the slope of the slope member.

Referring again to FIG. 4, Alignment layers 11 and 21 are formed on the inner surfaces of the two panels 100 and 200 described above, respectively. The alignment layers 11 and 21 may be vertical alignment layers. In exemplary embodiments, polarizing films (not shown) may be provided on the outer surfaces of the two panels 100 and 200, respectively, and the transmission axes of the polarizing films may be perpendicular to each other, in which one transmission axis is parallel to the gate lines 121. In alternative exemplary embodiments, in a reflective liquid crystal display, one polarizing film may be omitted.

In another exemplary embodiment, one retardation film (not shown) for compensating for the delay of the liquid crystal layer 3 may be interposed between the panels 100 and 200 and the polarizing films. The retardation film has birefringence and serves to reversely compensate for the birefringence of the liquid crystal layer 3. One exemplary embodiment of the retardation film may include a mono-axial optical film or a biaxial optical film Another exemplary embodiment of the retardation film, may include a negative mono-axial optical film.

In another exemplary embodiment, spacer members (not shown) to maintain the gap between the thin film transistor panel 100 and the common electrode panel 200 are formed between the two panels 100 and 200. In one exemplary embodiment, the spacer members may include an insulating material.

In another exemplary embodiment, the liquid crystal display may include a backlight unit for supplying light to the polarizing films, the retardation films, the two panels 100 and 200, and the liquid crystal layer 3.

The liquid crystal layer 3 has negative dielectric anisotropy, and the liquid crystal molecules 31 of the liquid crystal layer 3 are aligned such that the major axes thereof are almost perpendicular to the surfaces of the two panels 100 and 200 without any electric field. Therefore, incident light does not pass through the orthogonal polarizing films and is blocked.

When a common voltage is applied to the common electrode 270 and the data voltages are applied to the pixel electrodes 190, an electric field substantially perpendicular to the surfaces of the panels 100 and 200 is generated. Alignment of the liquid crystal molecules 31 is changed in response to the electric field such that the major axes thereof are perpendicular to the electric field. The slope members 330a to 330c of the common electrode 270, the cut portions 91, 92a, and 92b of the pixel electrodes 190, and the edges of the pixel electrodes 190 essentially determine the tilt direction of the liquid crystal molecules 31, which will be described below in detail.

The liquid crystal molecules 31 are pre-tilted by the slope members 330a to 330b in the absence of an electric field. When the liquid crystal molecules 31 are pre-tilted, the liquid crystal molecules 31 are tilted in the pre-tilted direction with application of an electric field, and the tilt direction is perpendicular to the edges of the cut portions 91, 92a, and 92b and the edges of the pixel electrodes 190.

On the other hand, the cut portions 91, 92a, and 92b of the pixel electrodes 190 and the edges of the pixel electrodes 190 parallel to the cut portions 91, 92a, and 92b distort the electric field to generate a horizontal component, which determines the tilt direction. The horizontal component of the electric field is perpendicular to the edges of the cut portions 91, 92a, and 92b and the edges of the pixel electrodes 190.

An equipotential surface of the electric field varies due to the difference in thickness of the slope members 330a to 330b, thereby applying a tilting force to the liquid crystal molecules 31. The tilting force also has a direction parallel to the tilt direction determined by the cut portions 91, 92a, and 92b and the slope members 330a to 330c. This arrangement is especially notable when the dielectric constant of the slope members 330a to 330c is smaller than that of the liquid crystal layer 3.

Advantageously, the tilt direction of the liquid crystal molecules 31 apart from the cut portions 91, 92a, and 92b and the oblique sides of the pixel electrodes 190 is determined, thereby enhancing the response speed of the liquid crystal molecules 31.

On the other hand, as shown in FIG. 1, one set of cut portions members 91, 92a, and 92b and one set of slope members 330a to 330c divide one pixel electrode 190 into plural sub-areas having two primary edges. The liquid crystal molecules 31 of each sub-area are tilted in the tilt direction described above. In exemplary embodiments, the tilt direction may include approximately four different relative directions. In this way, by making the tilt directions of the liquid crystal molecules 31 various, the reference viewing angle of the liquid crystal display can be enhanced.

The singular portions H and P of the slope members 330a to 330b may arrange the liquid crystal molecules 31 in the vicinity of the ridges of the slope members 330a to 330c to correspond to the shapes of the singular portions H and P, thereby preventing the tilt direction of the liquid crystal molecules in the vicinity of the ridges from being disturbed. When the singular portions H and P are not provided, the pre-tilt is not established in the vicinity of the ridges of the slope members 330a to 330c, and the two horizontal components of the electric field generated with cut portions have the same magnitude and opposite directions. Accordingly, the two horizontal components are cancelled. When the singular portions H and P are not provided, the liquid crystal molecules 31 in the vicinity of the ridges may not easily determine the tilt direction or the tilt directions frequently varies, thereby slowing the total response time of the liquid crystal molecules 31.

In exemplary embodiments, since the tilt direction of the liquid crystal molecules 31 can be determined by the use of only the cut portions 91, 92a, and 92b of the pixel electrodes 190 and the slope members 330a to 330c, the cut portions may not be provided in the common electrode 270. Accordingly, a process of patterning the common electrode 270 may be omitted. Since electric charges are not accumulated at specific positions by omitting the cut portions from the common electrode 270, it is possible to prevent the electric charges from moving to and damaging the polarizing films 22. Accordingly, an electrostatic discharge preventing process for preventing the damage of the polarizing films can be omitted. Advantageously, the omission of the cut portions may remarkably reduce the cost for manufacturing the liquid crystal display.

However, when no cut portion is formed in the common electrode 270, defective alignment of the liquid crystal molecules may occur. In an exemplary embodiment of the present invention, a plurality of hollows 61 are formed in the cut portions 91, 92a, and 92b of the pixel electrodes 190, thereby assisting the alignment of the liquid crystal molecules 31.

The depth “C” of the hollows 61 is in the range of 20% to 100% of the length L3 from the ridge and perpendicular to the bottom of the slope, and the cut portions 91, 92a, and 92b of the pixel electrodes 190 are formed at positions opposed to the bottom of the slope of the slope members 330a to 330c. When a voltage is applied thereto, the liquid crystal molecules 31 are aligned parallel to the depth direction of the hollows 61 due to the hollows 61.

As shown in FIG. 5, the liquid crystal molecules 31 disposed substantially within the hollows 61 are affected by the hollows 61 and are arranged parallel to the hollows 61 in the depth direction of the hollows 61. Since the alignment direction of the liquid crystal molecules 31 arranged by the cut portions 91, 92a, and 92b is equal to the alignment direction of the liquid crystal molecules 31 positioned in the hollows 61, the alignment of the liquid crystal molecules 31 is improved.

Advantageously, by forming a plurality of hollows 61 for assisting the alignment of the liquid crystal molecules 31 in the cut portions 91, 92a, and 92b of the pixel electrodes 190, it is possible to improve a white afterimage. A visual inspection method or an inspection method using on-off response waveforms may be used to estimate a level of a white afterimage. In the visual inspection method, “0” denotes “No white afterimage”, “1” denotes “weak white afterimage”, “3” denotes “middle white afterimage”, and “5” denotes “strong white afterimage.” In the inspection method using on-off response waveforms, assumed that a portion of a response waveform having the greatest height is denoted by “Max” and the height of a stabilized response waveform is denoted by “Sta”, it is considered that the white afterimage may be decreased as the value of Sta/Max×100(%) becomes closer to 100%.

When it is determined as a result of the visual inspection that no hollows 61 are formed, a disclination line is not fixed, but when it is determined as a result of the visual inspection that the hollows 61 are formed, the disclination line is fixed to a specific position, similarly to the case that the cut portions are formed in the common electrode. In this case, the value thereof is estimated as about “2.”

In the inspection method using a response waveform, when the hollows 61 are formed, a difference between the initial brightness of white and the stabilized brightness of white is decreased and the value thereof becomes closer to 100%.

Advantageously, by forming a plurality of hollows 61 at both ends of the cut portions where texture easily occurs, it is possible to align the liquid crystal molecules 31 so as to not be affected by a lateral electric field.

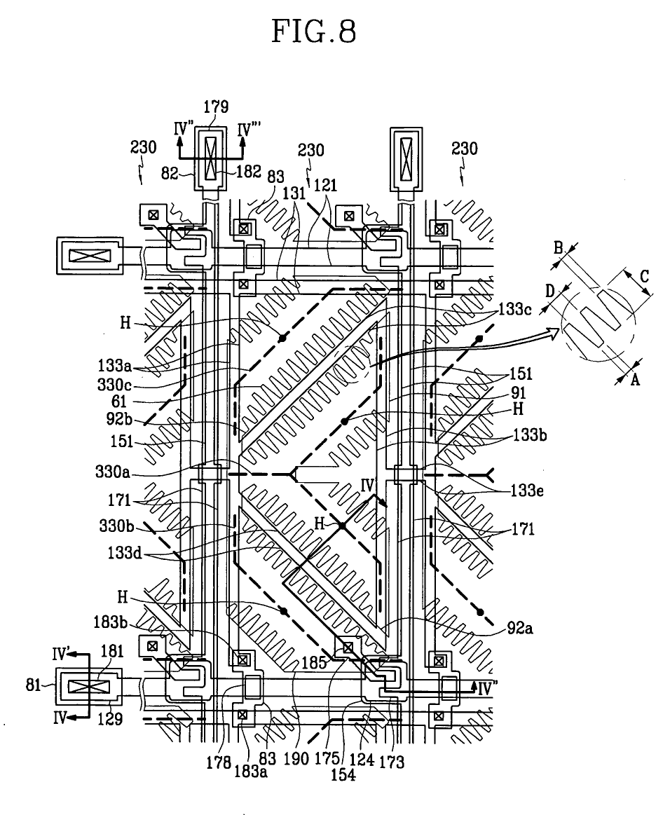

Next, another exemplary embodiment of a liquid crystal display according to the present invention will be described in detail with respect to FIG. 8.

FIG. 8 is a layout diagram illustrating another exemplary embodiment of a liquid crystal display according to the present invention.

The liquid crystal display of the exemplary embodiment has almost the same structure as that shown in FIGS. 1 to 4, except that the width of the hollows 61 becomes smaller toward the bottom of the hollows 61. That is, the width “D” at the entrance of the hollows 61 is greater than the width “A” at the bottom of the hollows 61.

In this case, since the electric field is formed toward the entrance of the hollows 61, the liquid crystal molecules 31 are more easily aligned in the depth “C” direction of the hollows 61 and the alignment of the liquid crystal molecules 31 can be more easily controlled.

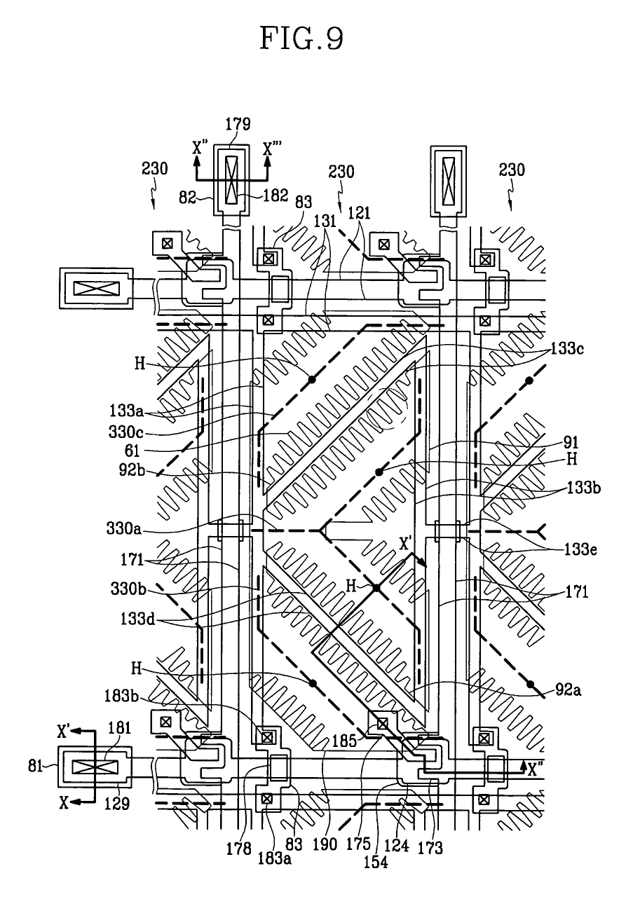

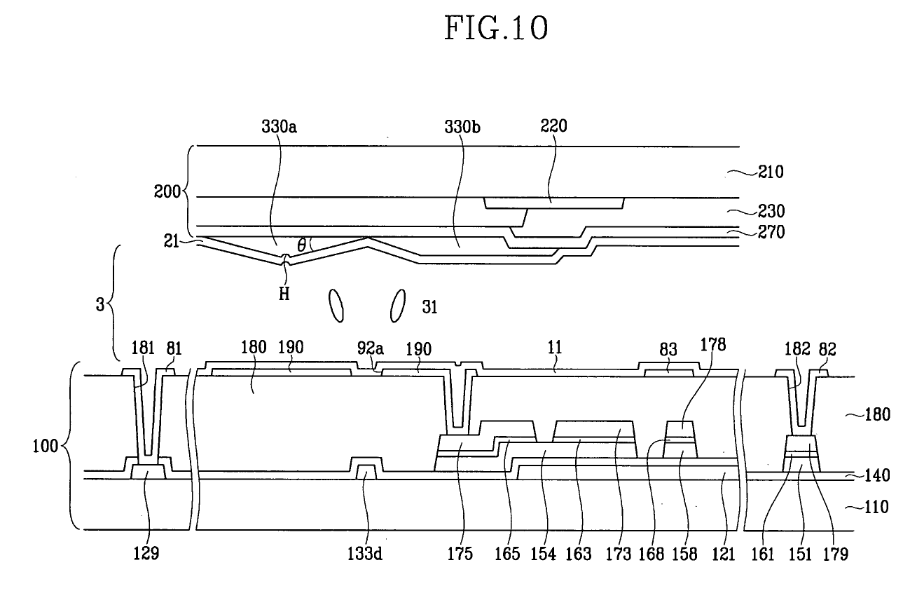

Next, another exemplary embodiment of a liquid crystal display according to the present invention will be described in detail with reference to FIGS. 9 and 10.

FIG. 9 is a layout diagram illustrating another exemplary embodiment of a liquid crystal display according to the present invention, and FIG. 10 is a cross-sectional view of the liquid crystal display taken along line X-X′-X″-X′″ of FIG. 9.

As shown in FIGS. 9 and 10, the liquid crystal display according to the exemplary embodiment includes a thin film transistor panel 100 and a common electrode panel 200 opposed to each other, and a liquid crystal layer 3 interposed therebetween.

The layered structures of the panels 100 and 200 according to the present embodiment are similar to those of the liquid crystal display shown in FIGS. 1 to 4.

In the thin film transistor panel 100, a plurality of gate lines 121 having gate electrodes 124 and end portions 129 and a plurality of storage electrode lines 131 having storage electrodes 133a to 133d are formed on a panel 110, and a gate insulating layer 140, a plurality of line-shaped semiconductor pattern 151 including extensions 154, a plurality of line-shaped ohmic contact members 161 having extensions 163, and a plurality of island-shaped ohmic contact members 165 are sequentially formed thereon. A plurality of data lines 171 including source electrodes 173 and end portions 179, a plurality of drain electrodes 175, and a plurality of isolated metal pieces 178 are formed on the ohmic contact members 161 and 165, and a passivation layer 180 is formed thereon. A plurality of contact holes 181, 182, 183a, 183b, and 185 are formed in the passivation layer 180 and the gate insulating layer 140, and a plurality of pixel electrodes 190 having cut portions 91, 92a, and 92b, a plurality of contact assistants 81 and 82, and a plurality of overpasses 83 are formed thereon.

In the common electrode panel 200, a light blocking member 220 having a plurality of openings 225, a plurality of color filters 230, a common electrode 270, and an alignment layer 21 are formed on an insulating panel 210.

Unlike the liquid crystal display shown in FIGS. 1 to 4, in the liquid crystal display according to the present exemplary embodiment, the line-shaped semiconductor patterns 151 have substantially the same top shapes as the data lines 171, the drain electrodes 175, and the ohmic contact members 161 and 165. However, the extensions 154 of the line-shaped semiconductor patterns 151 have portions not covered with the data lines 171 and the drain electrodes 175 between the source electrodes 173 and the drain electrodes 175.

The thin film transistor panel 100 according to the present exemplary embodiment includes a plurality of island-shaped semiconductor patterns 158 which are disposed below the metal pieces 178 and which have substantially the same shape at a top portion as a corresponding portion of the metal pieces 178 A plurality of ohmic contact members 168 are disposed on the semiconductor patterns 158.

In an exemplary embodiment of a method of manufacturing the thin film transistor according to the present invention, the data lines 171, the drain electrodes 175, the metal pieces 178, the semiconductor patterns 151, and the ohmic contact members 161 and 165 may be formed through a same or single photolithography process.

A photoresist film used in the photolithography process has different thicknesses at various positions and includes first portions and second portions. The first portions have a thickness that is greater than that of the second portions. The first portions may be positioned in wiring regions occupied by the data lines 171, the drain electrodes 175, and the metal pieces 178, and the second portions are positioned in channel regions of the thin film transistors.

An exemplary embodiment of a method of changing the thickness of the photoresist film may include a method of providing a translucent area to an optical mask in addition to a light transmitting area and a light blocking area. The translucent area is provided with a slit pattern, a lattice pattern, or a thin film having middle transmissivity or middle thickness. When the slit pattern is used, the width of the slits or the gap between the slits may be smaller than the resolution of an exposing apparatus used in the photolithography process. One exemplary embodiment may include a method employing a photoresist film which can reflow. That is, a photoresist film that can reflow is formed by the use of a general exposure mask having only the light transmitting area and the light blocking area, and the photoresist film is allowed to reflow into the areas where the photoresist film has not remained, thereby forming the thin portions.

Advantageously, since the photolithography process can be omitted once, the manufacturing method can be simplified.

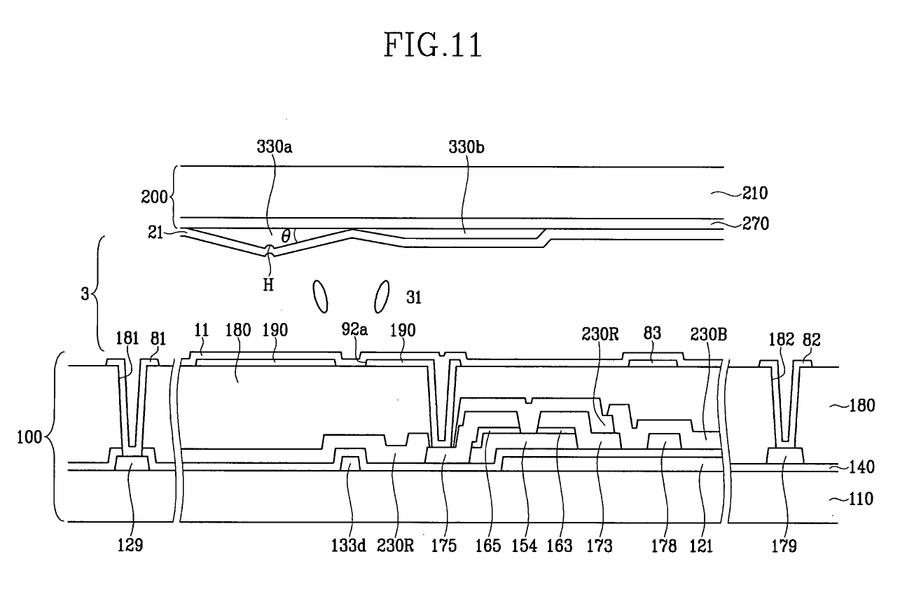

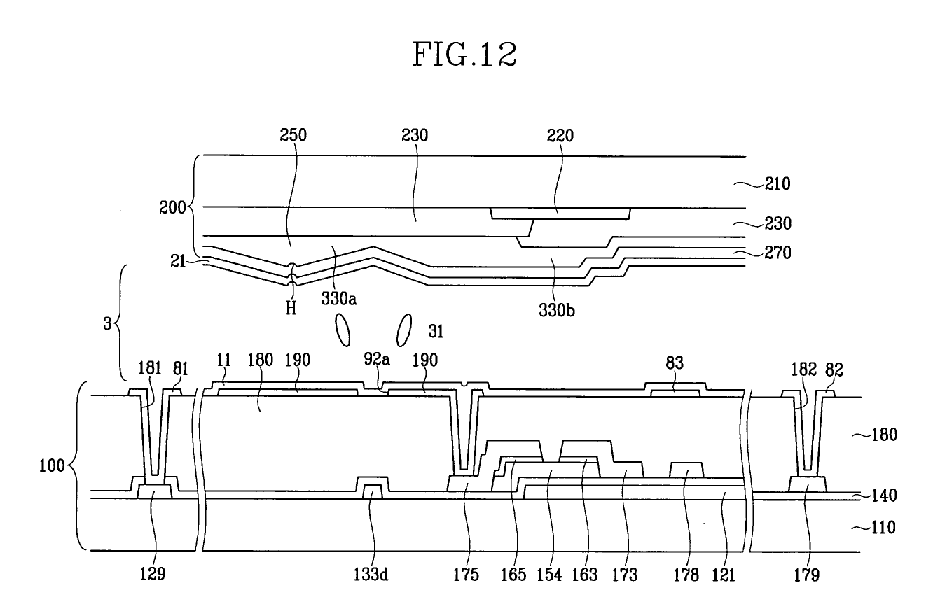

In alternative exemplary embodiments, many features of the exemplary embodiments of the liquid crystal display shown in FIGS. 1 to 4 may be applied to the exemplary embodiments of the liquid crystal display shown in FIGS. 11 and 12.

FIG. 11 is a cross-sectional view taken along Line IV-IV′-IV″-IV′″ of FIG. 1 as another exemplary of the cross-sectional view of the liquid crystal display shown in FIGS. 1 to 3.

As shown in FIG. 11, the liquid crystal display according to the present exemplary embodiment includes a thin film transistor panel 100 and a common electrode panel 200 opposed to each other, and a liquid crystal layer 3 interposed therebetween.

The layered structures of the panels 100 and 200 according to the present embodiment are similar to those of the liquid crystal display shown in FIGS. 1 to 4.

In the thin film transistor panel 100, a plurality of gate lines 121 having gate electrodes 124 and end portions 129 and a plurality of storage electrode lines 131 having storage electrodes 133a to 133d are formed on a panel 110, and a gate insulating layer 140, a plurality of line-shaped semiconductor patterns 151 including extensions 154, a plurality of line-shaped ohmic contact members 161 having extensions 163, and a plurality of island-shaped ohmic contact members 165 are sequentially formed thereon.

A plurality of data lines 171 including source electrodes 173 and end portions 179, a plurality of drain electrodes 175, and a plurality of isolated metal pieces 178 are formed on the ohmic contact members 161 and 165, and a passivation layer 180 is formed thereon. A plurality of contact holes 181, 182, 183a, 183b, and 185 are formed in the passivation layer 180 and the gate insulating layer 140, and a plurality of pixel electrodes 190 having cut portions 91, 92a, and 92b, a plurality of contact assistants 81 and 82, and a plurality of overpasses 83 are formed thereon.

In the common electrode panel 200, a common electrode 270, a plurality of slope members 330a and 330b, and an alignment layer 21 are formed on an insulating panel 210.

Unlike the liquid crystal display shown in FIGS. 1 to 4, in the exemplary embodiment of the liquid crystal display according to the present embodiment, no color filter is formed on the common electrode panel 200, but a plurality of color filters 230R, 230G, and 230B are formed under the passivation layer 180 of the thin film transistor panel 100. The color filters 230R, 230G, and 230B extend vertically along the columns of the pixel electrodes 190, and neighboring color filters 230R, 230G, and 230B may overlap with each other on the data lines 171. The color filters 230R, 230G, and 230B may include, but are not limited to, colors of red, green, and blue. The color filters 230R, 230G, and 230B overlapping with each other essentially form a light blocking member for blocking light leaking between the neighboring pixel electrodes 190. Advantageously, the light blocking member 220 may be omitted from the common electrode panel 200, thereby simplifying the processes.

In exemplary embodiments, an interlayer insulating layer (not shown) may be disposed under the color filters 230.

In exemplary embodiments of the liquid crystal display shown in FIGS. 9 and 10, the color filters 230 may be disposed under the passivation layer 180 of the thin film panel 100.

In alternative exemplary embodiments, many features of the liquid crystal display shown in FIGS. 1 to 4 may be applied to the liquid crystal display shown in FIG. 11.

Another exemplary embodiment of a liquid crystal display according to the present invention will be described in detail with reference to FIG. 12.

FIG. 12 is a cross-sectional view taken along Line IV-IV′-IV″-IV′″ of FIG. 1 as another exemplary embodiment of the cross-sectional view of the liquid crystal display shown in FIGS. 1 to 3.

As shown in FIG. 12, the liquid crystal display according to the present exemplary embodiment includes a thin film transistor panel 100 and a common electrode panel 200 opposed to each other, and a liquid crystal layer 3 interposed therebetween.

The layered structures of the panels 100 and 200 according to the present embodiment are similar to those of the liquid crystal display shown in FIGS. 1 to 4.

In the thin film transistor panel 100, a plurality of gate lines 121 having gate electrodes 124 and end portions 129, and a plurality of storage electrode lines 131 having storage electrodes 133a to 133d are formed on a panel 110, and a gate insulating layer 140, a plurality of line-shaped semiconductor patterns 151 including extensions 154, a plurality of line-shaped ohmic contact members 161 having extensions 163, and a plurality of island-shaped ohmic contact members 165 are sequentially formed thereon. A plurality of data lines 171 including source electrodes 173 and end portions 179, a plurality of drain electrodes 175, and a plurality of isolated metal pieces 178 are formed on the ohmic contact members 161 and 165, and a passivation layer 180 is formed thereon. A plurality of contact holes 181, 182, 183a, 183b, and 185 are formed in the passivation layer 180 and the gate insulating layer 140, and a plurality of pixel electrodes 190 having cut portions 91, 92a, and 92b, a plurality of contact assistants 81 and 82, and a plurality of overpasses 83 are formed thereon.

In the common electrode panel 200, a light blocking member 220 having a plurality of openings 225, a common electrode 270, a plurality of color filters 230, a plurality of slope members 330a and 330b, and an alignment layer 21 are formed on an insulating panel 210.

In the liquid crystal display shown in FIG. 12, unlike the embodiment described with FIGS. 1 to 4, the slope members 330a to 330c are not separately formed on the common electrode 270, but are formed by processing an overcoat layer 250 on the color filters 230 and under the common electrode 270.

The overcoat layer 250 is a layer serving to essentially protect the color filters 230, to prevent the leakage of pigments from the color filters 230, and to provide a substantially flat plane. In exemplary embodiments, the overcoat layer 250 is particularly advantageous where cut portions (not shown) are formed in the common electrode 270 to expose the color filters 230.

In alternatively exemplary embodiments, instead of forming the slope members 330a and 330b integrally with the overcoat layer 250, the slope members 330a and 330b may be separately formed on the overcoat layer 250.

In other alternative embodiments, features of the liquid crystal display shown in FIGS. 1 to 4 may be applied to the liquid crystal display shown in FIG. 12.

As described above, in the embodiments of the present invention, by adding the slope members to tilt the liquid crystal molecules, it is possible to enhance the response speed of the liquid crystal molecules and thus to manufacture a liquid crystal display that can display a moving image.

In addition, since the slope members assist the alignment of the liquid crystal molecules, the cut portions may not be formed in the common electrode. Accordingly, since a process of patterning the common electrode can be omitted, it is possible to prevent damage due to introduction of static electricity.

Furthermore, by forming a plurality of hollows in the cut portions of the pixel electrodes, which serve to assist the alignment of the liquid crystal molecules, it is possible to prevent defective alignment of the liquid crystal molecules that might occur because the cut portions are not formed in the common electrode.

Although the exemplary embodiments of the present invention have been described in detail, the present invention is not limited to the embodiments, but may be modified in various forms without departing from the scope of the appended claims. Therefore, it is natural that such modifications belong to the scope of the present invention.

What is claimed is:

1. A liquid crystal display comprising:
a panel;
a first electric field generating electrode formed on the panel;
a second electric field generating electrode opposed to the first electric field generating electrode;
a liquid crystal layer disposed between the first electric field generating electrode and the second electric field generating electrode;
a slope member formed on the panel and comprising a ridge and a slope, and
a plurality of hollows formed in a cut portion of the second electric field generating electrode.

2. The liquid crystal display of claim 1, wherein the hollows are formed substantially perpendicular to a longitudinal direction of the cut portion.

3. The liquid crystal display of claim 1, wherein the cut portion is opposed to a bottom of the slope of the slope member.

4. The liquid crystal display of claim 1, wherein a depth of each hollow is in the range of about 20% to about 100% of a length from the ridge and perpendicular to a bottom of the slope member.

5. The liquid crystal display of claim 1, wherein a width of each hollow is in the range of about 1 μm to about 4 μm.

6. The liquid crystal display of claim 1, wherein a gap between hollows is in the range of about 1 μm to about 4 μm.

7. The liquid crystal display of claim 1, wherein a width of each hollow is substantially the same at an entrance of the hollow and at a bottom of the hollow.

8. The liquid crystal display of claim 1, wherein a width of each hollow decreases in a direction from an entrance of the hollow to a bottom of the hollow.

9. The liquid crystal display of claim 1, wherein a depth of each hollow decreases in a direction from the center of the cut portion toward ends of the cut portion.

10. The liquid crystal display of claim 1, wherein a singular portion is formed in the ridge.

11. The liquid crystal display of claim 10, wherein the singular portion is a concave portion.

12. The liquid crystal display of claim 10, wherein the singular portion is a convex portion.

13. The liquid crystal display of claim 10, wherein the singular portion is substantially symmetric about the ridge.

14. The liquid crystal display of claim 10, wherein a width of the singular portion extending from the ridge in a direction perpendicular to the ridge is in the range of about 10 μm to about 15 μm and a length of the singular portion extending along the ridge is 20 μm or less.

15. The liquid crystal display of claim 10, wherein a bottom surface or a top surface of the singular portion is flat.

16. The liquid crystal display of claim 10, wherein a bottom surface or a top surface of the singular portion is curved.

17. The liquid crystal display of claim 10, wherein the first electric field generating electrode covers the whole surface of the panel.

18. The liquid crystal display of claim 10, wherein a slope angle of the slope is in the range of about 1° to about 10°.

19. The liquid crystal display of claim 10, further comprising a plurality of slope members, wherein an area of the plurality of slope members is greater than or equal to half of an area of the second electric field generating electrode.

20. The liquid crystal display of claim 10, wherein the singular portion is positioned substantially at the center of the ridge.

21. The liquid crystal display of claim 10, wherein two or more singular portions are disposed in the ridge.

22. The liquid crystal display of claim 1, wherein the slope is bent.

23. The liquid crystal display of claim 1, wherein a height of the ridge ranges from about 0.5 μm to about 2.0 μm.

24. The liquid crystal display of claim 1, further comprising a plurality of color filters formed below the first electric field generating electrode.

25. The liquid crystal display of claim 1, further comprising a plurality of color filters formed below the second electric field generating electrode.

26. The liquid crystal display of claim 24, further comprising an overcoat layer formed between the first electric field generating electrode and the color filters.

27. The liquid crystal display of claim 26, wherein the slope member is disposed between the overcoat layer and the first electric field generating electrode.

28. The liquid crystal display of claim 24, wherein the slope member is formed integrally with the overcoat layer.

29. A method of forming a liquid crystal display comprising:
forming a first electric field generating electrode panel;
forming a second electric field generating electrode opposite the first electric field generating electrode;
disposing a liquid crystal layer between the first electric field generating electrode and the second electric field generating electrode;
forming a slope member on the panel, the slope member comprising a ridge and a slope, and
forming a plurality of hollows in a cut portion of the second electric field generating electrode.
